(19) United States
(12) Patent Application Publication
(10) Pub. No.: US 2004/0160742 A1
(43) Pub. Date: Aug. 19, 2004

(54) Three-dimensional electrical device packaging employing low profile elastomeric interconnection

(76) Inventor: Roger E. Weiss, Foxborough, MA (US)

Correspondence Address: Brian M. Dingman, Mirick, O'Connell, DeMallie & Lougee, LLP, 1700 West Park Drive, Westborough, MA, 01581-3941, US

(21) Appl. No.: 10/776,948

(22) Filed: Feb. 11, 2004

Related U.S. Application Data
(60) Provisional application No. 60/447,858, filed on Feb. 14, 2003.

(51) Int. Cl. H05K 7/20

(52) U.S. Cl. 361/712; 361/714; 361/716

(57) ABSTRACT

A compliant interconnect for compactly, releasably packaging vertically-spaced electrical devices. The compliant interconnect includes at least one substrate for supporting and electrically connecting to the electrical devices, a layer of anisotropic conductive elastomer (ACE) between each electrical device and each immediately adjacent electrical device, and a layer of ACE between the substrate and the electrical device closest to the substrate. The ACE layers provide electrical connection through the package, and also conduct heat from the electrical devices. There is also a device that applies a compressive load to each of the ACE layers

### CROSS-REFERENCE TO RELATED APPLICATION

This application claims priority of provisional application serial number 60/447,858 filed on Feb. 14, 2003.

### FIELD OF THE INVENTION

This invention relates to a high density, three-dimensional electrical device package.

### BACKGROUND OF THE INVENTION

Anisotropic Conductive Elastomer (ACE) is a composite of conductive metal elements in an elastomeric matrix. ACE is typically constructed such that it conducts along one axis only. In general, ACE is made to conduct through its thickness. ACE can be fabricated to have anisotropic conductivity by mixing magnetic particles with a liquid resin, forming the mix into a continuous sheet, and curing the sheet in the presence of a magnetic field that is normal to the surface of the sheet. This results in the particles forming electrically conductive columns through the sheet thickness. The resulting structure is both flexible and anisotropically conductive. These properties provide for an electrical interconnection medium having varied uses and applications.

Traditional electronic packaging incorporates single electrical devices which are attached to a printed circuit board with solder, or alternatively using some means of accomplishing separable electrical interconnection. FIG. 1 presents one example of a prior art separable device connection using ACE. Device 2 (for example, a chip carrier) is connected to printed circuit board 1 using ACE layer 3. The compressive force required for the ACE layer conductivity is provided by a combination of heat sink 4, backing plate 5, and spring plate 6. This planar style of packaging uses significant board space, and the resulting long path between components can limit the speed of the system.

As a result of these and other limitations, there have been several proposals to vertically stack electrical components. Vertically stacking (3D packaging) of components can result in a lower volume, better PCB utilization and higher system performance. However, the heat generation associated with 3D packaging is a challenge, and the permanent solder or wire bonding of layers can result in a non-repairable stack with severe impact on system manufacturing yield.

### SUMMARY OF THE INVENTION

The present invention provides for a low profile 3D packaging capability which is separable. It also provides for improved heat removal, high performance vertical interconnection, and simplified assembly.

ACE materials can be constructed which are very thin and therefore use little vertical space. A typical ACE material can be as thin as 0.010″ and less. Circuit devices which incorporate a vertical bus structure can be can be vertically aligned and interconnected using ACE as the interconnection medium. A compressive load applied to the stack will simultaneously compress all of the ACE layers, thus inerconnecting the components to create the vertical bus.

This invention features a compliant interconnect for compactly, releasably packaging vertically-spaced electrical devices. The interconnect comprises at least one substrate for supporting and electrically connecting to the electrical devices, a layer of anisotropic conductive elastomer (ACE) electrically interconnecting each electrical device and each immediately adjacent electrical device, a layer of ACE electrically interconnecting the substrate and the electrical device closest to the substrate to at least contribute to a vertical electrical bus. The ACE layers provide electrical connection through the package, and also conduct heat from the electrical devices. The interconnect further includes a device for applying a releasable compressive load to each of the ACE layers. The substrate may comprise a printed circuit board.

The compliant interconnect may further comprise one or more spacer members that define one or more wells into which electrical devices can be placed. The spacer members may be electrically connected to the vertical bus. The electrical connection of the spacer members may be accomplished with ACE.

The compliant interconnect may further comprise a support layer arranged under at least one electrical device. The support layer may carry electrical signals, and may comprise a heat-conductive element, to conduct heat laterally away from the electrical device. The compliant interconnect may further include a heat-exchange device coupled to the heat-conductive element. The heat-exchange device may comprise one or more heat pipes, or one or more heat sinks. The device for applying a releasable compressive load may be coupled to at least one heat pipe.

In a more specific embodiment, the invention may be accomplished in a compliant interconnect for packaging compactly, releasably vertically-spaced electrical devices, comprising at least one substrate for supporting and electrically connecting to the electrical devices, a series of vertically-adjacent spacer members together defining a well in which the electrical devices are located, the spacer members each comprising a support layer spanning the well and supporting and electrically connecting to a device, a layer of ACE between each spacer member and each immediately adjacent spacer member, and a layer of ACE between the substrate and the spacer member closest to the substrate, wherein the ACE layers provide electrical connection through the package, and also conduct heat from the electrical devices. This embodiment also includes a device for applying a compressive load to each of the ACE layers.

The spacer members may comprise vertically thickened portions outside of the well. At least one spacer member may further comprise a heat-conductor for carrying heat away from the supported device. The compliant interconnect may further comprise a heat sink in thermal contact with the one or more of the heat conductors of one or more of the spacer members, to help dissipate heat from the devices. The compliant interconnect may further comprise one or more heat pipes in thermal contact with one or more of the spacer members, to help dissipate heat from the spacer members.

### BRIEF DESCRIPTION OF THE DRAWINGS

Other objects, features and advantages will occur to those skilled in the art from the following description of the preferred embodiments, and the accompanying drawings, in which:

FIG. 1 is an elevational view of a prior art planar style of separable electrical device packaging;

FIG. 2 is a highly schematic, enlarged, cross-sectional view of one embodiment of a 3D package of the invention;

FIG. 3 is a similar diagram of an alternative preferred embodiment in which the substrates form wells for the electrical devices and also conduct heat away from the devices;

FIG. 4 is a similar diagram of another alternative preferred embodiment in which the wells are formed by separate spacer members rather than the substrates; and

FIG. 5 is a similar view of yet another alternative preferred embodiment similar to that shown in FIGS. 3 and 4, but without wells, to accommodate low-profile electrical devices.

### DETAILED DESCRIPTION OF THE PREFERRED EMBODIMENTS

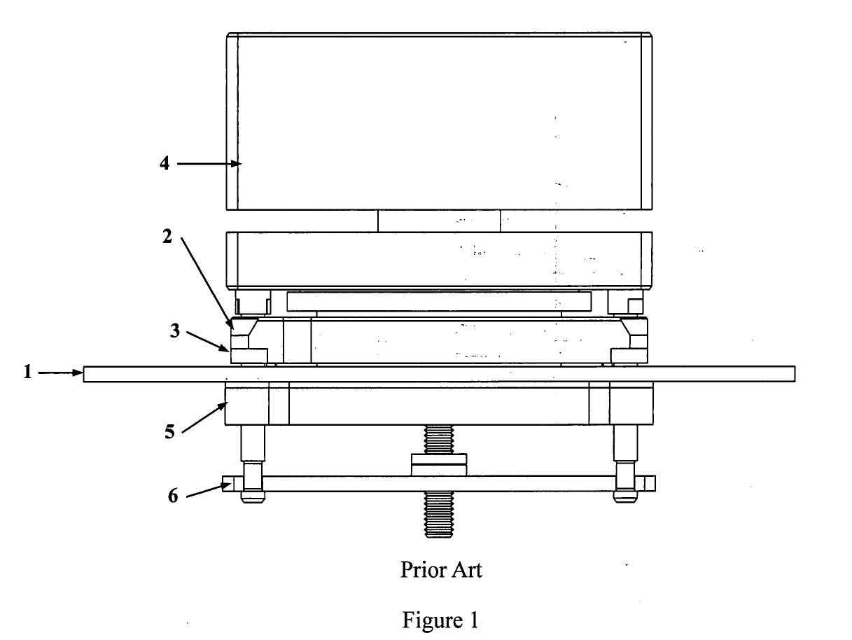

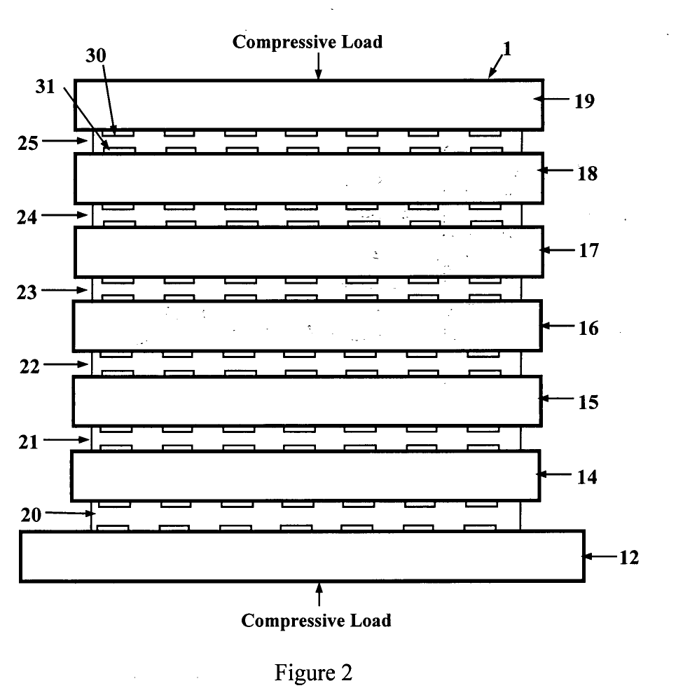

FIG. 2 depicts a 3D package 10 of the invention. The relative scale of the various components has been adjusted to provide visual clarity. Package 10 accomplishes the compliant interconnection of the invention for a stack of electrical devices 14-19. ACE layers 20-25 are located between adjacent electrical devices, and between the lowest electrical device 14 and PC board substrate 12. ACE layers 20-25 provide electrical interconnection along the vertical electrical bus comprised of electrical contacts and circuits such as contacts 30 and 31 that are on the upper and lower surface of each ACE layer and/or on the adjacent devices 14-19. This provides the necessary and desired inter-layer electrical contact through the stack. Since the ACE layers are both electrically and thermally conductive in the vertical direction due to the embedded conductive metal elements, the ACE layers 20-25 also serve to conduct heat through the stack, to assist with cooling of the electrical devices 14-19. Arrows are used in FIG. 2 to indicate the direction of force that is applied to generate the compressive load necessary for electrical continuity through all of the ACE layers. A releasable compression system such as that shown in FIG. 1, or another system as known in the art, can be used to provide the compression. This can be accomplished mechanically (as shown in FIG. 1) or by other means such as electromechanical devices and hydraulic devices. The vertical bus includes contact zones on the top and bottom surface of each individual electrical device and package, as appropriate (not shown), which can be used to provide inter-layer electrical contact. Package 10 can consist of several independent packages, or several devices making up a single package.

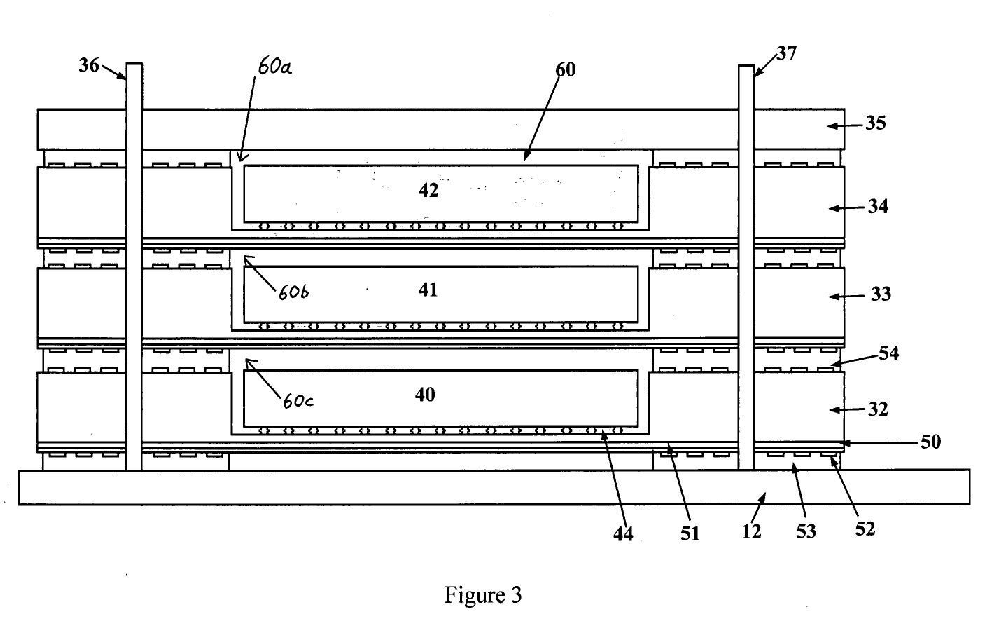

The vertical electrical interconnect within the stack can be either integral to the package of electrical devices being interconnected, as in FIG. 2, or outside the package as depicted in FIG. 3. The ACE material between each layer of the package provides the vertical electrical interconnect, and also participates in the conduction of heat. A single pair of compressive elements can be applied to generate a compressive load for all layers. The use of ACE layers allows simple assembly and disassembly.

Removal of the heat generated by the devices in the 3D stack of devices is a concern with 3D packaging. Means to laterally remove the heat using metal structures, coupled with cooling methods such as fans, heat pipes or liquid cooling, can assist the heat transfer accomplished by the ACE layers. In one preferred embodiment of the invention, a metal core packaging technology is employed to both house the electrical device and to provide a means to conduct heat laterally from the device. FIG. 3 presents one embodiment of such.

The FIG. 3 arrangement comprises PC board substrate 12 and electrical devices 40-42 that are located in stack area 60 comprised of wells 60a, 60b and 60c. Wells 60a-60c are defined by a series of vertically-spaced aligned spacer members 32-34. Each spacer member 32-34 comprises a support layer such as layer 51 of member 32 that spans well 60c and supports and electrically connects to device 40 having electrical contacts 44. The multi-layer PC board-like construction of the support layers/spacer members is not shown. The support layers/spacer members also preferably include a heat-conductor for carrying heat away from the supported device. In FIG. 3 this comprises metal layer 51 that conducts heat away from device 40 to cooling channels 36 and 37. Channels 36 and 37 can be fluid-containing pipes. They can act as heat pipes (in which a state change of the fluid is involved in the heat transfer) or be part of a circulated fluid heat exchange system.

Spacer members 32-34 each comprise a metal core which is coated with alternating layers of insulator material (such as epoxy or Kapton), and conducting layers (such as would be found in a multilayer printed circuit board). The total structure has the form of a multi-layer board which is constructed on a metal sheet. The multi-layer structure is constructed such that a well is formed to house the integrated circuit device. The device can be in the flip chip format mounted using solder bump technology. Heat will be laterally conducted in the metal core. Vertical cooling elements (or elements arranged other than vertically) will conduct the heat away. In the example of FIG. 3, vertical cooling tubes are shown using liquid cooling to remove the heat. The ACE material serves the dual purpose of electrical interconnect and inter-layer fluid seal. Although a liquid cooling system is shown in the example, other means such as heat pipes, forced air, and heat fins could also be employed

As described above, in the embodiment shown in FIG. 3, the vertical electrical interconnect is outside of stack area 60 containing devices 40-42. This is accomplished in a manner similar to that described above using intervening layers of ACE material such as layer 53 and contacts located on the surfaces of the ACE such as contacts 52 and 54. Also shown is upper compression plate 35 that provides the compressive force necessary to accomplish electrical continuity through the layers of ACE material. This plate could be mounted on pins or other structures that transfer force between plate 35 and PC board 12 or other compressive structures such as the arrangement shown in FIG. 1. Such pins could also accomplish registration of all of the elements to the underlying PCB 12.

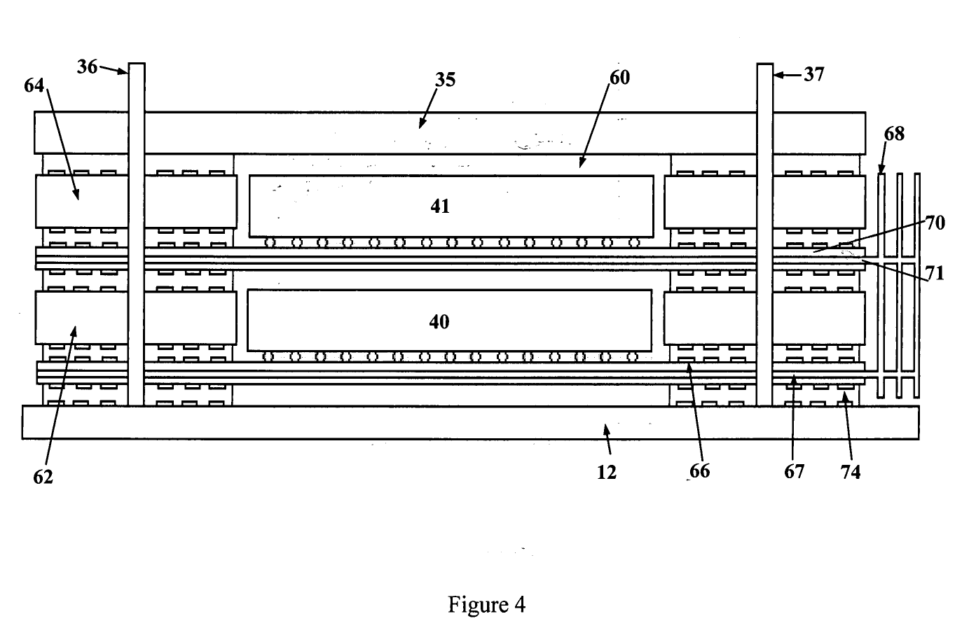

The well in which each electrical device is mounted could be built into the PC board as shown in FIG. 3, or created by separate members used as spacers around the device, as indicated in FIG. 4. The use of such a spacer allows for the package to be assembled using conventional assembly methodology. FIG. 4 also presents an alternative means of removing heat. An extension of the metal plate into a fin structure allows the heat to be removed by convection or forced air.

FIG. 4 achieves the same vertical stacking as the embodiment of FIG. 3, but in this case rather than integral vertically thickened portions such as portion 50 of spacer member 32, FIG. 3, FIG. 4 discloses separate structures 62 and 64 that provide the vertical spacing, and also are part of the vertical electrical bus. Structures 62 and 64 can be shaped like frames. The arrangement of FIG. 4 decouples the vertical spacers from the horizontal supports, electrical connectors and heat conductors. This provides more flexibility in that the depth and arrangement of the wells can be accomplished in a modular fashion to accommodate different types and sizes and quantities of electrical devices such as devices 40 and 41.

Spacer structures 62 and 64 are also component parts of the vertical bus interconnecting board 12 and devices 40 and 41. Members 66 and 70 each include support layers 67 and 71, respectively, that function like support layer 51, FIG. 3. Different size and thickness spacer structures and support members allow the configuration of FIG. 4 to be adapted to hold one or more electrical devices that can be of different size and shape as accommodated by the particular size, shape and thickness of structures 62 and 64. Cooling channels 36 and 37 can also be used. Compression plate 35 provides the compressive force for the ACE layers.

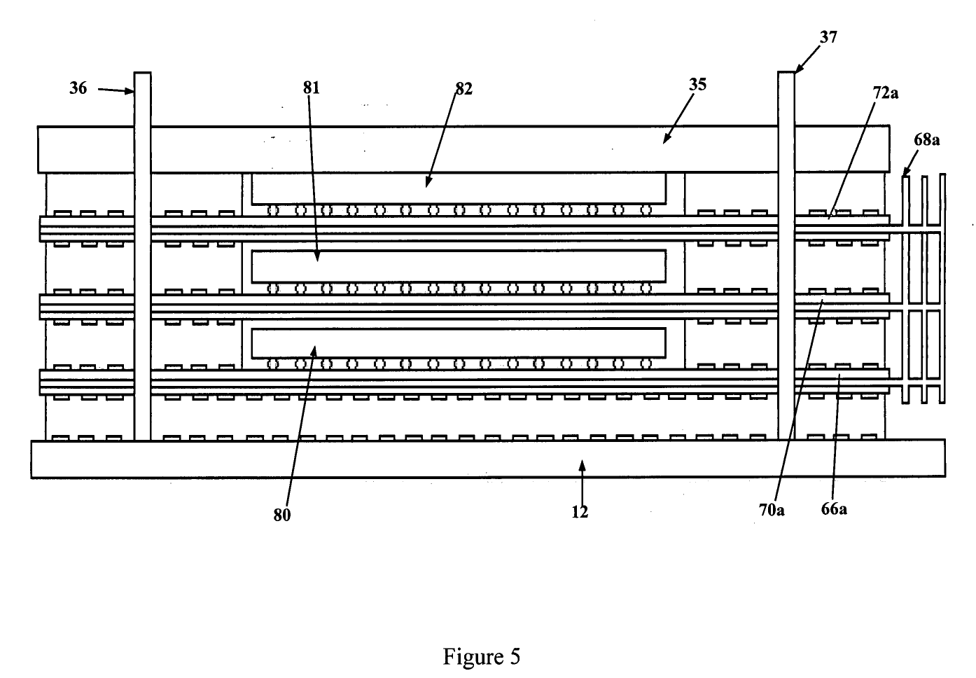

FIG. 5 presents a further refinement of the invention where, for use with thin devices, no spacer is needed, and a vertical bus is created on each unit of the assembly. Furthermore, in this embodiment the stack is shown to be comprised (for example) of a processor and RAM memory. Since the stack may be separable, it can be more easily modified to upgrade the memory/processor as needed. The modular nature of the design allows low cost customization. The very short path length between the vertically-spaced devices facilitates very high speed signal propagation.

FIG. 5 details another embodiment that can accommodate thinner electrical devices 80-82. This is effectively the same as FIG. 4 but without the vertical spacers 62 and 64, illustrating in the flexibility of the design concept of FIGS. 4 and 5.

Another feature of the invention as a whole shown in FIGS. 4 and 5 is external heat sink or other heat dissipater 68, 68a that is in thermal contact with conductive layers 67 and 71 to assist in heat dissipation from the stack of devices.

Members 66a, 70a and 72a accommodate three devices. The quantity of members can be modified, and separate vertically thickened portions such as spacer members 62 and 64 (FIG. 4) can be used as necessary in one or more layers to accommodate different arrangements of electrical devices.

Like the embodiments of FIGS. 3 and 4, the embodiment of FIG. 5 includes support and spacer members 66a, 70a and 72a separated and electrically interconnected to one another and to underlying board 12 with intervening layers of ACE. This embodiment is effectively identical to the embodiment of FIG. 4 but without the vertical spacer members 62 and 64. This embodiment could also be accomplished with spacers in one or more of the layers to accommodate a combination of thinner and thicker electrical devices.

The examples demonstrate various embodiments of the invention. Several other arrangements of the bus structure and heat removal system will become obvious once the invention shown here is disclosed.

Alignment of the stack can be accomplished in several ways. One preferred method is to use a pair of registration pins which are mounted in the main board. Each component would have a matching pair of holes. The stack would be assembled on these pins and then clamped into compression.

Other embodiments will occur to those skilled in the art and are within the following claims.

What is claimed is:

1. A three-dimensional electrical device package for compactly packaging vertically-spaced electrical devices, comprising:
a plurality of vertically-spaced electrical devices;
a layer of anisotropic conductive elastomer (ACE) electrically interconnected between each electrical device and each immediately adjacent electrical device, the ACE layers providing electrical connection through the package to at least contribute to a vertical electrical bus, and also conduct heat from the electrical devices;
one or more spacer members that define one or more wells into which electrical devices can be placed, the spacer members each comprising a support for at least one electrical device; and
a device for applying a releasable compressive load to each of the ACE layers.

2. The three-dimensional electrical device package of claim 1, further comprising at least one substrate for supporting and electrically connecting to the electrical devices.

3. The three-dimensional electrical device package of claim 2, further comprising a layer of ACE electrically interconnected between the substrate and the electrical device closest to the substrate.

4. The three-dimensional electrical device package of claim 2, wherein the substrate comprises a printed circuit board.

5. The three-dimensional electrical device package of claim 1, wherein the spacer members are electrically connected to the vertical bus.

6. The three-dimensional electrical device package of claim 5, wherein the electrical connection of the spacer members are accomplished using ACE.

7. The three-dimensional electrical device package of claim 1, wherein the spacer members further comprise a heat-conductive element within the support, to conduct heat laterally away from the electrical device.

8. The three-dimensional electrical device package of claim 7, wherein the spacer members further comprise electrical conductors in electrical contact with the supported device.

9. The three-dimensional electrical device package of claim 7 further comprising a heat-exchange device coupled to the heat-conductive elements.

10. The three-dimensional electrical device package of claim 9, wherein the heat-exchange device comprises one or more heat pipes.

11. The three-dimensional electrical device package of claim 9, wherein the heat-exchange device comprises one or more heat sinks.

12. The three-dimensional electrical device package of claim 9, wherein the heat-exchange device comprises a heat exchanger employing a flowing liquid.

13. The three-dimensional electrical device package of claim 10, wherein the device for applying a releasable compressive load is coupled to at least one heat pipe.

14. The three-dimensional electrical device package of claim 1, wherein the spacer members carry electrical signals.

15. The three-dimensional electrical device package of claim 14, wherein the package comprises a number of vertically-adjacent layers, each layer comprising a spacer member.

16. The three-dimensional electrical device package of claim 15, wherein ACE layers electrically interconnect the vertically-spaced spacer members.

17. The three-dimensional electrical device package of claim 1, wherein the spacer members comprise vertically thickened portions outside of the stack area, to create wells for the electrical devices.

18. A compliant interconnect for compactly, releasably packaging vertically-spaced electrical devices, comprising:
at least one substrate for supporting and electrically connecting to the electrical devices;
a series of vertically-adjacent spacer members together defining a stack area in which the electrical devices are located, the spacer members each comprising a support layer spanning the well, and supporting and electrically connecting to at least one electrical device;
a layer of ACE between each spacer member and each immediately adjacent spacer member;
a layer of ACE between the substrate and the spacer member closest to the substrate;
wherein the ACE layers provide electrical connection through the package, and also conduct heat from the electrical devices; and
a device for applying a compressive load to each of the ACE layers.

19. The compliant interconnect of claim 18, wherein the spacer members comprise vertically thickened portions outside of the stack area, to create wells for the electrical devices.

20. The compliant interconnect of claim 18, wherein at least one spacer member further comprises a heat-conductor for carrying heat away from the supported device.

21. The compliant interconnect of claim 20 further comprising a heat sink in thermal contact with the one or more of the heat conductors of one or more of the spacer members, to help dissipate heat from the devices.

22. The compliant interconnect of claim 20 further comprising one or more heat pipes in thermal contact with one or more of the spacer members, to help dissipate heat from the spacer members.

23. The compliant interconnect of claim 20, further comprising a heat exchanger employing a flowing liquid in thermal contact with one or more of the spacer members.

24. A three-dimensional electrical device package for compactly packaging vertically-spaced electrical devices, comprising:
a plurality of vertically-spaced electrical devices;
a layer of anisotropic conductive elastomer (ACE) electrically interconnecting each electrical device to each immediately adjacent electrical device, the ACE layers providing electrical connection through the package to at least contribute to a vertical electrical bus, and also conduct heat from the electrical devices;
one or more support layers that each support and electrically connect to at least one electrical device, the support layers comprising a heat-conductive element, to conduct heat laterally away from the supported electrical devices;
one or more heat pipes thermally coupled to the heat-conductive elements of the support layers; and
a device for applying a releasable compressive load to each of the ACE layers.

25. The three-dimensional electrical device package of claim 24, wherein the device for applying a releasable compressive load is mechanically coupled to at least one of the heat pipes.
